(19) United States
(12) Patent Application Publication
(10) Pub. No.: US 2025/0300082 A1
(43) Pub. Date: Sep. 25, 2025

(54) POWER DELIVERY NETWORK VIAS

(71) Applicant: Micron Technology, Inc., Boise, ID (US)

(72) Inventors: Dan E. Soto, Boise, ID (US); Dale Arnold, Meridian, ID (US)

(21) Appl. No.: 19/047,937

(22) Filed: Feb. 7, 2025

Related U.S. Application Data
(60) Provisional application No. 63/567,175, filed on Mar. 19, 2024.

(51) Int. Cl. H01L 23/528; H01L 23/522

(52) U.S. Cl. CPC H01L 23/5286; H01L 23/5226

(57) ABSTRACT

A power delivery network includes an array of first vias arranged on a particular plane of the power delivery network to form a particular shape on the particular plane. The power delivery network further includes an array of second vias with at least one via of the array of second vias arranged at a location within the particular shape on the particular plane.

### PRIORITY INFORMATION

This application claims the benefit of U.S. Provisional Application No. 63/567,175, filed on Mar. 19, 2024, the contents of which are incorporated herein by reference.

### TECHNICAL FIELD

Embodiments of the disclosure relate generally to electronic systems, and more specifically, relate to power delivery network (PDN) vias.

### BACKGROUND

Electronic devices, such specialized circuits like Application-Specific Integrated Circuits (ASICs) and/or memory devices, rely on power management for reliable operation. The delivery of electrical power within these electronic devices is an important factor influencing overall performance of the electronic devices.

### BRIEF DESCRIPTION OF THE DRAWINGS

The present disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example electronic system including a power delivery network in accordance with some embodiments of the present disclosure.

FIG. 2A is a three-dimensional view of a portion of a power delivery network including power and ground vias arranged on power and ground planes in accordance with some embodiments of the present disclosure.

FIG. 2B is a top view of a portion of an example power delivery network including power and ground vias arranged on power and ground planes in accordance with some embodiments of the present disclosure.

FIG. 3 is a top view of a portion of another example power delivery network including power and ground vias arranged on power and ground planes in accordance with some embodiments of the present disclosure.

FIG. 4 is a top view of a portion of another example power delivery network including power and ground vias arranged on power and ground planes in accordance with some embodiments of the present disclosure.

### DETAILED DESCRIPTION

Aspects of the present disclosure are directed to power delivery network (PDN) vias. As used herein, the term “PDN” refers to a system of components that delivers electrical power from a power source to a load. A PDN can be an important component in electronic systems designed to efficiently supply electrical power to various components on a printed circuit board (PCB). A PDN includes a network of power and ground planes, conductive traces, decoupling capacitors, and other elements strategically arranged to distribute power across various components of the PCB.

A PDN can be a multilayer PDN, which can include inner and outer layers. The outer layers can include top and bottom layers, on which components and signal traces can be located. For example, primary components can be located on the top layer, while additional components can be located on the bottom layer. The inner layer is located between two outer (e.g., top and bottom) layers and can include power and ground planes. The inner layer can consist of one internal layer (e.g., “core layer”) and additional internal layers (for the multiple-layer PCB). The power plane distributes voltage to components, while the ground plane provides a return path for electrical currents, helping to maintain a stable ground reference.

A number of vias (e.g., power vias, ground vias, etc.) can be located within the one or more internal layers (e.g., between the power and ground planes) to allow electrical signals to pass through different layers of the PDN (e.g., in association with power delivery). As used herein, the term “power via” refers to a via that serves as a pathway that delivers electrical power from the power source (such as a power plane in the PCB) to the components that need power. Further, as used herein, the term “ground via” refers to a via that serves as a conductive path to connect different layers of a PCB to establish a stable ground reference. The height of the vias (e.g., power vias, ground vias, etc.) can affect and/or be a major portion of the thickness of the internal layers, which can be as thick as required by the PCB in controller packages.

A PDN structure may be desired to be designed in a manner that reduces loop inductance. Loop inductance is a property of the PDN that contributes to the total impedance of the structure. The reduced inductance and resistance of the power delivery path can help with maintaining signal integrity by preventing voltage drops and reducing noise, which improves the performance and power efficiency of the system. However, some approaches often adopt the increased core thickness (e.g., the thickness of the internal layers, which can be generally proportional to the height of the vias of the PDN as mentioned above) in the pursuit of the improved manufacturability, which inevitably introduces the higher loop inductance and increased susceptibility to noise interference. Furthermore, when the route for delivering power to the printed circuit board (PCB) becomes longer due to increased core thickness, it can impact the stability of transmitted voltage and diminish the speed of voltage transfer.

Aspects of the present disclosure address the above and other deficiencies by providing a reduced loop inductance without further decreasing the core thickness. For example, embodiments of the present disclosure provide a closer proximity (e.g., a reduced pitch distance) between ground and power vias as compared to prior approaches. By placing ground vias close to power vias, the return current path can be kept short and close to the path of the outgoing current. This reduces the loop area, which is crucial for reducing electromagnetic interference (EMI) and maintaining a low impedance profile, which helps in maintaining a stable voltage level and reduces the impact of noise and other disturbances.

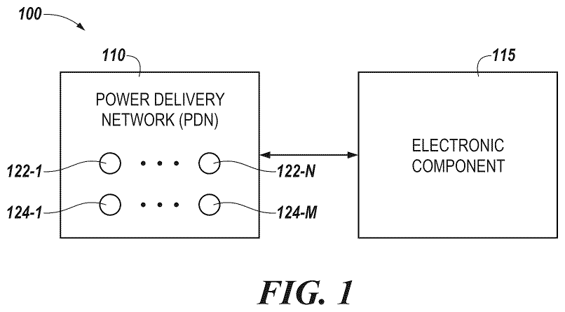

FIG. 1 illustrates an example electronic system 100 including a power delivery network 110 in accordance with some embodiments of the present disclosure. For clarity, the electronic system 100 has been simplified to focus on features with particular relevance to the present disclosure.

The electronic system 100 can be, or can be part of, for example, a desktop computer, laptop computer, televisions, home theater system, gaming console, digital camera, network router and/or switch, printer, scanner, medical device, GPS navigation device, home device (e.g., thermostat, doorbell camera, security camera, smart lock, etc.), wearable device, industrial control system (e.g., automated industrial and/or control device) mobile computing device, a vehicle (e.g., airplane, drone, train, automobile, or other conveyance), Internet of Things (IoT) enabled device, embedded computer (e.g., one included in a vehicle, industrial equipment, or a networked commercial device), system-on-chip (SoC), chipset (e.g., a collection of integrated circuits), tile, Field-Programmable Gate Array (FPGA) structure (e.g., segmented FPGA structure), or other such device.

The electronic system 100 can include a power delivery network (PDN) 110. As used herein, the term “power delivery network” can refer to a network of components and structures designed to deliver electrical power from the power source (e.g., voltage regulators, power supplies, etc.) to the various electronic components, such as electronic component 115. Although not specifically illustrated in FIG. 1, the PDN 110 can be distributed across multiple layers of a printed circuit board (PCB).

Although a single electronic component 115 is shown in FIG. 1, the PDN 110 of system 100 can be coupled to multiple electronic components 115, which can include various electronic circuits, devices, etc. such as integrated circuits (ICs), transistors, diodes, resistors, capacitors, inductors, connectors, switches, sensors, memory devices, voltage regulators, power management ICs, light-emitting diodes, crystal oscillators, radio frequency (RF) modules, etc.; although, embodiments are not so limited. Electronic components 115 can also be memory devices, which can include volatile memory devices, such as (but not limited to) random access memory (RAM), such as dynamic random-access memory (DRAM) and synchronous dynamic random access memory (SDRAM) or nonvolatile memory, such as negative-and (NAND) type flash memory, read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, and electrically erasable programmable read-only memory (EEPROM). In a number of embodiments, the electronic component 115 can be positioned (e.g., mounted) on the same PCB where the PDN 110 is distributed.

Although embodiments are not so limited, in some embodiments, the electronic system 100 can be a controller package, such as Application-Specific Integrated Circuit (ASIC) package (e.g., 8-layer package) with a PDN (e.g., the PDN 110) to supply power to various components of the controller package, such as logic gates, memory cells, clocking components, input/output circuits, signal circuits, power management units, control circuits (e.g., ASICs), sensors, etc.

Although not specifically illustrated in FIG. 1, the PDN 110 can be a multilayer PDN, which can include outer layers (including top and bottom layers, for example) and an inner layer located between the two outer layers. Although embodiments are not so limited, a memory component 115 can be located on the outer layers (e.g., top and/or bottom layers) of the PDN 110.

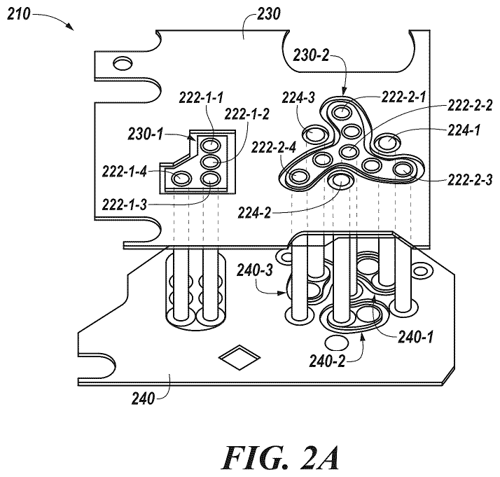

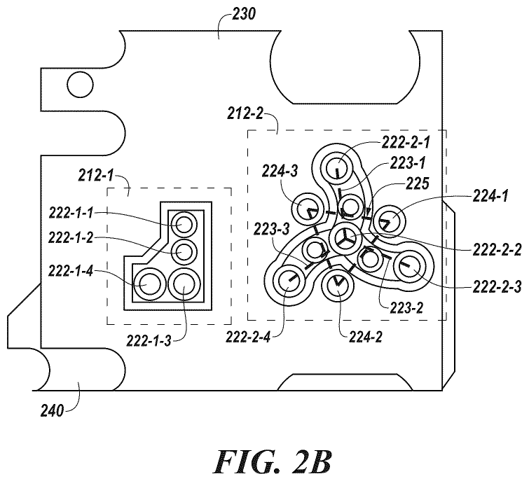

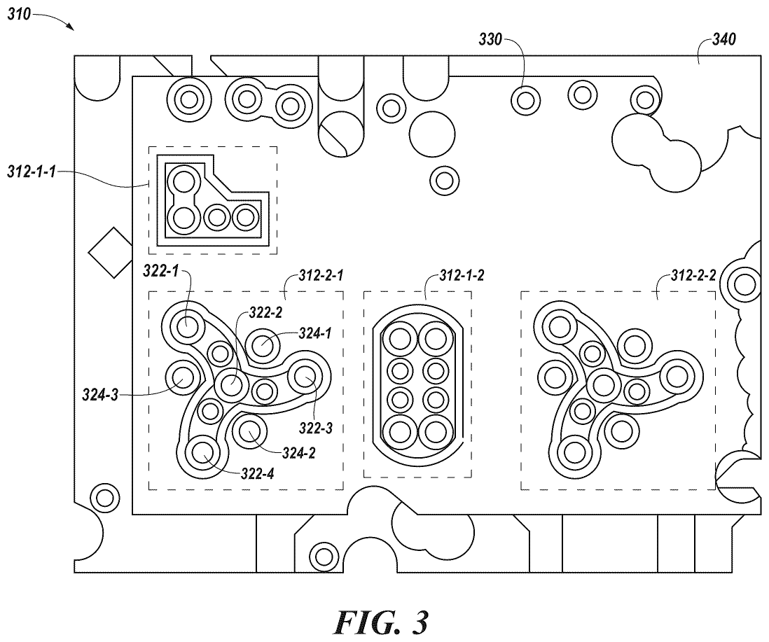

The inner layer can consist of multiple planes, such as power planes (e.g., power plane 230, 330 illustrated in FIGS. 2 and 3, respectively), ground planes (e.g., ground plane 240, 3440 illustrated in FIGS. 2 and 3, respectively), etc. These multiple planes of the inner layer can often be coupled through vias, such as ground vias 122-1, . . . , 122-N (collectively referred to as “ground vias 122”), power vias 124-1, . . . , 124-M (collectively referred to as “power vias 124”), etc. These two different types of vias (power vias 124 and ground vias 122) can form a looping current path (which includes a path of an electrical current traveling from a source and returning to its point of origin); thereby, further forming a loop area (e.g., the enclosed area corresponding to the looping current path). In a number of embodiments, ground vias 122 and power vias 124 can be arranged on either the ground plane or the power plane in a manner that reduces the loop area to further reduce the loop inductance. Further details of the arrangement are illustrated and described in association with FIGS. 2-4.

FIG. 2A is a three-dimensional view of a portion of a power delivery network including power and ground vias arranged (e.g., at various locations) on power and ground planes in accordance with some embodiments of the present disclosure. The PDN 210 illustrated in FIG. 2A can be analogous to the PDN 110 of FIG. 1.

A PDN 210 can include a number of vias that can be of different types. For example, as illustrated in FIG. 2A, the PDN 210 includes ground vias 222-2-1, 222-2-2, 222-2-3, and 222-2-4 (collectively referred to as ground vias 222-2), such as at one region 212-1 illustrated in FIG. 2B and power vias 224-1, 224-2, and 224-3 (collectively referred to as power vias 224) and ground vias 222-1-1, 222-1-2, 222-1-3, and 222-1-4 (collectively referred to as ground vias 222-1), such as at a different region 212-2 illustrated in FIG. 2B. As used herein, the term “region” refers to a particular functional or operational region (e.g., on a particular plane, such as a power plane 230 or a ground plane 240) on which a respective array of vias (e.g., arrays of ground vias 222-1 and 222-2 or an array of power vias 224) is arranged. The PDN 210 is not illustrated in its entirety in FIG. 2A. For example, the PDN 210 can further include ball grid arrays (BGAs) pad, solder bumps (alternatively referred to as “BGA balls”), etc. (e.g., in those portions of the PDN 210 not illustrated in FIG. 2A) that are not illustrated in FIG. 2A.

As illustrated in FIG. 2A, the PDN 210 includes at least two different planes, such as a power plane 230 and a ground plane 240. As illustrated in FIG. 2A, the power vias 224 are arranged on (e.g., coupled to) the power plane 230 on one end and the ground plane 240 on another end, while the ground vias 222 are arranged on (e.g., coupled to) the ground plane 240 on one end and the power plane 230 on another end. More particularly, the arrays of ground vias 222-1 and 222-2 are respectively arranged on openings on the power plane 230. For example, as illustrated in FIG. 2A, the array of ground vias 222-1 is arranged within the opening 230-1 formed on the power plane 230, while the array of ground vias 222-2 is arranged within the opening 230-2 formed on the power plane 230. Similarly, each power via of the array of power vias 224-1, 224-2, and 224-3 is arranged on a respective opening 240-1, 240-2, and 240-3 formed on the ground plane 240.

As illustrated in FIG. 2A, the array of power vias 224 is located adjacent to the array of ground vias 222 (e.g., at least on the region 212-2 illustrated in FIG. 2B), while the array of ground vias 222-1 is arranged (e.g., on the region 212-1 illustrated in FIG. 2B) not adjacent to the array of power vias 224 (e.g., external to the shape 225) on the power plane 230. Power vias (e.g., power vias 224) located adjacent to ground vias (e.g., ground vias 222) can provide benefits, such as reduced loop inductance without increasing the core thickness. For example, the close proximity among ground and power vias allows the return current path (current flowing back to the ground) to be close to the path of the outgoing current; thereby, reducing the loop area. This reduced loop area reduces the loop inductance, which helps in maintaining a stable voltage level and reduces the impact of noise and other disturbances. Further, the reduced loop inductance due to the reduced loop area eliminates a need for increasing the number of power vias (to enhance power delivery); thereby, avoiding the potential risk of heightened noise interference due to the increased number of power vias.

Meanwhile, an increased quantity of ground vias on a PDN (e.g., the PDN 210) can contribute to lowering the overall resistance of the PDN. For example, ground vias respectively provide parallel paths for the return current to flow. This parallelization of paths can help reduce the overall resistance of the PDN, which is desirable for efficient power delivery, especially in high-speed and high-frequency electronic designs.

FIG. 2B is a top view of a portion of an example power delivery network 210 including power and ground vias arranged (e.g., at various locations) on power and ground planes in accordance with some embodiments of the present disclosure. The power delivery network 210 illustrated in FIG. 2B can be analogous to the power delivery network 210 illustrated in FIG. 2A. For example, power vias 224-1, 224-2, and 224-3 illustrated in FIG. 2B can be analogous to power vias 224-1, 224-2, and 224-3 illustrated in FIG. 2A; ground vias 222-2-1, 222-2-2, 222-2-3, and 222-2-4 illustrated in FIG. 2B can be analogous to ground vias 222-2-1, 222-2-2, 222-2-3, and 222-2-4 illustrated in FIG. 2A; and ground vias 222-1-1, 222-1-2, 222-1-3, and 222-1-4 illustrated in FIG. 2B can be analogous to ground vias 222-1-1, 222-1-2, 222-1-3, and 222-1-4 illustrated in FIG. 2A. Further, those ground vias 222 and/or power vias 224 on each region can be formed on the same BGA ball, although embodiments are not so limited. For example, ground vias 222-1 can be formed on one BGA ball, while ground vias 222-2 and power vias 224 can be formed on another BGA ball.

An array of power vias 224 (e.g., power vias 224-1, 224-2, and 224-3) on the region 212-2 is arranged at various locations on the power plane 230 to form a closed shape (alternatively referred to as “perimeter”), such as a triangular shape 225 as illustrated in FIG. 2B. As used herein, the term “closed shape” refers to a shape where the constituent endpoints form a continuous and unbroken boundary, allowing the closed shape to have a region. The triangular shape 225 has power vias 224-1, 224-2, and 224-3 as respective vertices. An array of ground vias 222 on the region 212-2 is further arranged on the power plane 230 to form an open shape. As used herein, the term “open shape” refers to a shape that has distinct endpoints that do not connect to form a complete boundary (thereby, not forming a closed loop). Although FIG. 2B illustrates three power vias 224 on the region 212-2, embodiments are not limited to a particular quantity of power vias that can be located adjacent to the ground vias. Additionally, embodiments are not limited to a particular quantity of ground vias to which power vias can be adjacent within the region.

As illustrated in FIG. 2B, at least one of the ground vias 222 (e.g., the ground via 222-2-2) is located (e.g., arranged at a location) within the triangular shape 225 formed by the array of power vias 224. Alternatively speaking, the via 222-2-2 is located internal to the perimeter corresponding to the triangular shape 225. In some embodiments, the ground via 222-2-2 can be located approximately at a center of the triangular shape 225.

As illustrated in FIG. 2B, the array of power vias 224 is located adjacent to the array of ground vias 222-2 at least at region 212-2. As an example, a pitch (alternatively referred to as “core via pitch”) between the ground via 222-2-2 and the power via 224-1 can be 175 micrometer (um), while the pitch between the ground via 222-2-4 and the power via 224-2 can be 182 um. However, embodiments are not so limited as the spacing between the power vias 224 and ground vias 222 can be dominated by the substrate space/trace requirements. For example, a thicker core material and/or thicker copper may require greater spacing that thinner core material and thinner copper.

The array of power vias 224 being located adjacent to the array of ground vias 222-2 allows two shapes respectively formed by the array of power vias 224 and the array of ground vias 222 to respectively overlap each other, with at least one line segment of one shape intersecting one line segment of the other shape. For example, a line segment (e.g., drawn) between the ground via 222-2-2 and any one of the ground vias 222-2-1, 222-2-3, and 222-2-4 intersects (e.g., crosses or passes through) a shape formed by the array of the power vias 224. Alternatively speaking, the line segment (e.g., corresponding to one of the sides of the triangular shape 225) between two endpoints (e.g., the power vias 224-1 and 224-2) interests with the line segment 223-2 between two endpoints, such as the ground vias 222-2-2 and 222-2-3 the line segment (e.g., corresponding to one of the sides of the triangular shape 225) between two endpoints (e.g., the power vias 224-2 and 224-3) interests with the line segment 223-3 between two endpoints, such as the ground vias 222-2-2 and 222-2-4 and the line segment (e.g., corresponding to one of the sides of the triangular shape 225) between two points (e.g., the power vias 224-1 and 224-3) interests with the line segment 223-1 between two endpoints, such as the ground vias 222-2-1 and 222-2-2.

The arrangement of power vias 224 in relation to ground vias 222-2 can reduce the loop inductance compared to previous approaches that do not employ the close proximity between power and ground vias. As an example, the close proximity of power and ground vias as illustrated in FIG. 2B can lower the loop inductance by 16 (when the core thickness is 200 um) to 33% (when the core thickness is 800 um) compared to the previous approaches. For example, when the core thickness is increased by the same amount, the arrangement of the PDN as illustrated in FIG. 2B can exhibit approximately one-third of the loop inductance compared to that of the previous approaches.

FIG. 3 is a top view of a portion of another example power delivery network 310 including power and ground vias arranged on power and ground planes in accordance with some embodiments of the present disclosure. Although FIG. 3 illustrates a particular quantity of power and ground vias in each region (e.g., regions 312-1-1, 312-1-2, 312-2-1, and 312-2-2), embodiments are not limited to a particular quantity of power and ground vias located in each region. Although embodiments are not so limited, the internal layers (e.g., core layer) of the example power delivery network 310 shown in FIG. 3 can be 400 um.

The power delivery network 310 is generally analogous to the power delivery network 210 illustrated in FIG. 2B except that it includes more regions that are analogous to the regions 212-1 and 212-2 illustrated in FIG. 2B. For example, similar to the region 212-1 illustrated in FIG. 2B, regions 312-1-1 and 312-1-2 can include ground vias only, while two regions 312-2-1 and 312-2-2 each can be analogous to the region 212-2 illustrated in FIGS. 2A and 2B. As illustrated in FIG. 3, the array of power vias 324-1, 324-2, and 324-3 (e.g., on the region 312-2-1) is arranged adjacent to the respective array of ground vias 322-1, 322-2, 322-3, and 322-4 in a similar manner as illustrated in FIG. 2B in which the array of power vias 224-1, 224-2, and 224-3 is arranged adjacent to the respective array of ground vias 222-1, 222-2, 222-3, and 222-4.

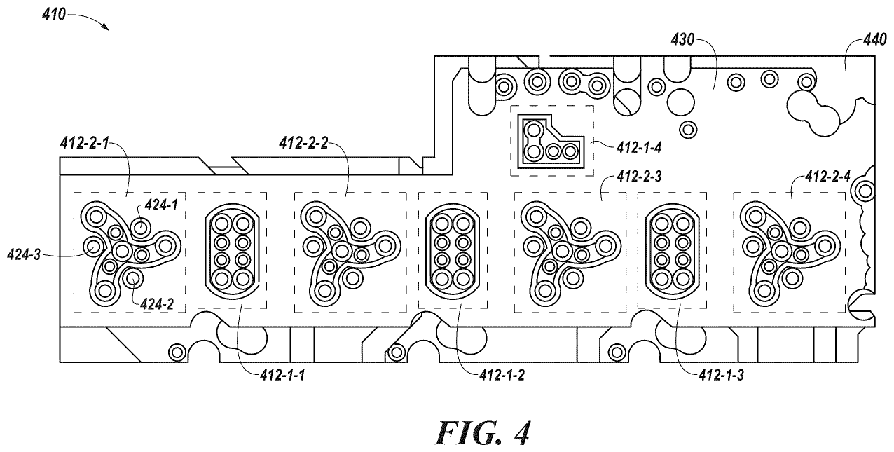

FIG. 4 is a top view of a portion of another example power delivery network 410 including power and ground vias arranged on power and ground planes in accordance with some embodiments of the present disclosure. Although FIG. 3 illustrates a particular quantity of power and ground vias in each region (e.g., regions 412-1-1, 412-1-2, 412-1-3, 412-1-4, 412-2-1, 412-2-2, 412-2-3, and 412-2-4), embodiments are not limited to a particular quantity of power and ground vias located in each region.

The power delivery network 410 is generally analogous to the power delivery network 210 illustrated in FIG. 2B except that it includes more regions that are analogous to the regions 212-1 and 212-2 illustrated in FIG. 2. For example, similar to the region 212-1 illustrated in FIG. 2B, four regions 412-1-1, 412-1-2, 412-1-3, and 412-1-4 can include ground vias only, while four regions 412-2-1, 412-2-2, 412-2-3, and 412-2-4 each can be analogous to the region 212-2 illustrated in FIG. 2. As illustrated in FIG. 3, the array of power vias 424-1, 424-2, and 424-3 (e.g., on the region 312-2-1) is arranged adjacent to the respective array of ground vias 422-1, 422-2, 422-3, and 422-4 in a similar manner as illustrated in FIG. 2B in which the array of power vias 224-1, 224-2, and 224-3 is arranged adjacent to the respective array of ground vias 222-1, 222-2, 222-3, and 222-4.

The arrangement of power vias 224, 324, and/or 424 in relation to ground vias 222 (e.g., 222-1), 322, and/or 422 can reduce the loop inductance compared to previous approaches that do not employ close proximity between power and ground vias. As an example, assuming that the core thickness is as 400 μm, the close proximity of power and ground vias as illustrated in FIGS. 2B, 3, and 4 can respectively lower the loop inductance by 23%, 11%, and 5% compared to the previous approaches. The arrangement of power vias 224, 324, and/or 424 in relation to ground vias 222 (e.g., 222-1), 322, and/or 422 can be substantially beneficial in regions with limited pins, such as Phase-Locked Loops (PLLs), and the vias as arranged in accordance with a number of embodiments of the present disclosure can significantly reduce loop inductance (e.g., particularly when placed in proximity to the memory die).

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A power delivery network, comprising:
an array of first vias arranged on a particular plane of the power delivery network to form a particular shape on the particular plane; and
an array of second vias with at least one via of the array of second vias arranged at a location within the particular shape on the particular plane.

2. The power delivery network of claim 1, wherein the particular shape corresponds to a triangular shape having locations on the particular plane on which the array of first vias are arranged as respective vertices of the particular shape.

3. The power delivery network of claim 2, wherein the at least one via of the array of second vias is arranged at a location on the particular plane corresponding to a center of the particular shape.

4. The power delivery network of claim 1, wherein the other vias of the array of second vias are arranged at respective locations external to the particular shape on the particular plane.

5. The power delivery network of claim 4, wherein:
a line segment having particular locations on the particular plane as two respective endpoints intersects at least one side of the particular shape on the particular plane, wherein the particular locations correspond to respective locations on the particular plane at which the at least one via of the array of second vias and one of the other vias of the array of second vias are arranged.

6. The power delivery network of claim 1, further comprising an additional array of second vias arranged at respective locations external to the particular shape on the particular plane.

7. The power delivery network of claim 1, wherein first vias of the array of first vias correspond to power vias for delivering power from a power source.

8. The power delivery network of claim 1, wherein second vias of the array of second vias correspond to ground vias for establishing a ground reference.

9. A power delivery network, comprising:
a first array of power vias arranged on a particular plane of a power delivery network to form a first shape on the particular plane; and
a first array of ground vias arranged on the particular plane of the power delivery network, wherein a first ground via of the array of ground vias is arranged at a location within the first shape on the particular plane, and wherein remaining ground vias of the array of ground vias are arranged at respective locations external to the first shape on the particular plane.

10. The power delivery network of claim 9, wherein:
the first array of ground vias are arranged on the particular plane to form a second shape on the particular plane, wherein the second shape corresponds to an open shape having locations on the particular plane on which ground vias of the first array of ground vias are arranged as respective endpoints.

11. The power delivery network of claim 9, wherein the remaining ground vias are arranged on the particular plane to form a particular closed shape having the respective locations as endpoints of the particular closed shape.

12. The power delivery network of claim 9, further comprising:
a second array of power vias arranged on the particular plane to form a second shape on the particular plane; and
a second array of ground vias arranged on the particular plane with at least one ground via of the second array of ground vias arranged at a location within the second shape on the particular plane.

13. The power delivery network of claim 12, wherein:
the second shape is located external to the first shape on the particular plane; and
a line segment having locations at which two ground vias of the second array of ground vias are arranged as respective endpoints does not intersect with the first shape.

14. The power delivery network of claim 12, wherein ground vias of the second array of ground vias are arranged at respective locations external to the first shape on the particular plane.

15. The power delivery network of claim 9, wherein the first shape corresponds to a closed shape.

16. A system, comprising:
an array of power vias arranged on a power plane to form a particular shape on the power plane; and
a plurality of arrays of ground vias, wherein at least one array of the plurality of arrays of ground vias arranged adjacent to the array of power vias on the power plane with at least one ground via of the at least one array of the plurality of arrays of ground vias arranged at a location within the particular shape on the power plane.

17. The system of claim 16, wherein:
at least one array of the plurality of arrays of ground vias is arranged adjacent to the array of power vias such that a first line segment having two locations on the power plane where two power vias of the array of power vias are arranged on as respective endpoints intersects with second line segment having two locations on the power plane where two ground vias of the at least one array of the plurality of arrays of ground vias are arranged on as respective endpoints.

18. The system of claim 17, wherein:
the at least one array of the plurality of arrays of ground vias is arranged within an opening formed on the power plane; and
the second line segment intersects the opening formed on the power plane at least at two points.

19. The system of claim 16, wherein the least one array of the plurality of arrays of ground vias is arranged on the power plane to form an open shape having locations where ground vias of the at least one array are arranged at as respective endpoints.

20. The system of claim 16, wherein ground vias of another array of the plurality of arrays of ground vias are arranged at respective locations external to the particular shape on the particular plane.
